(19) United States
(12) Patent Application Publication
(10) Pub. No.: US 2026/0275187 A1
(43) Pub. Date: Sep. 17, 2026

(54) QUANTUM DOT COMPOSITE MATERIAL, METHOD OF FORMING THE SAME AND LIGHT-EMITTING DEVICE

(71) Applicant: Ennostar Corporation, Hsinchu City (TW)

(72) Inventors: Lu-Ching WANG, Hsinchu City (TW); Pei-Cong YAN, Hsinchu City (TW); Hung-Chun TONG, Hsinchu City (TW); Yu-Chun LEE, Hsinchu City (TW)

(21) Appl. No.: 19/559,778

(22) Filed: Mar. 6, 2026

(30) Foreign Application Priority Data
Mar. 17, 2025 (TW) 114109778

(51) Int. Cl. C09K 11/02; C09K 11/88; H10K 50/115

(52) U.S. Cl. CPC C09K 11/025; C09K 11/883; H10K 50/115

(57) ABSTRACT

A quantum dot composite material is provided. The quantum dot composite material includes a carrier core; a plurality of quantum dot particles attached to the carrier core; and a composite protective layer covering the carrier core and the plurality of quantum dot particles, and including a cladding layer and a porous light-diffusion layer which include light-transmissive materials. The cladding layer is conformably formed on the carrier core and the plurality of quantum dot particles. The porous light-diffusion layer is formed on the cladding layer and includes an irregular surface.

### CROSS REFERENCE TO RELATED APPLICATIONS

This application claims priority of Taiwan patent application No. 114109778 filed Mar. 17, 2025, the entirety of which is incorporated by reference herein.

### TECHNICAL FIELD

The present disclosure relates to a quantum dot composite material and a method of forming the same, and, in particular, it relates to a quantum dot composite material having a light-diffusion layer and a method of forming the same.

### BACKGROUND

Due to the quantum confinement effect, the emission spectrum of quantum dots can be adjusted by particle size. The emission spectrum has a narrow full width at half maximum (FWHM), which enables the provision of high-purity colored light. Quantum dots have a wide range of applications and are currently used in fields such as light-emitting diodes (LEDs), lighting, solar cells, biological labeling, and displays.

However, quantum dots are often affected by moisture and/or oxygen in the environment, which may reduce their stability. This consequently diminishes their luminescence performance. Therefore, while existing quantum dots and their formation methods have gradually met their intended purposes, they still do not fully meet all requirements in every respect. Consequently, challenges remain to be overcome regarding quantum dots and their formation methods.

### BRIEF SUMMARY

An embodiment of the present disclosure provides a quantum dot composite material, comprising: a carrier core; a plurality of quantum dot particles attached to the carrier core; and a composite protective layer covering the carrier core and the plurality of quantum dot particles, and including a cladding layer and a porous light-diffusion layer which include light-transmissive materials. The cladding layer is conformably formed on the carrier core and the plurality of quantum dot particles. The porous light-diffusion layer is formed on the cladding layer and includes an irregular surface.

An embodiment of the present disclosure provides a method of forming the quantum dot composite material. The method comprises dispersing and attaching a plurality of quantum dot particles to a carrier core; forming a cladding layer conformably on the plurality of quantum dot particles and the carrier core; and forming a porous light-diffusion layer including an irregular surface on the cladding layer.

In addition, an embodiment of the present disclosure provides a light-emitting device, comprising the quantum dot composite material above.

### BRIEF DESCRIPTION OF THE DRAWINGS

Aspects of the present disclosure are best understood from the following detailed description when read with the accompanying figures. It should be emphasized that, in accordance with the standard practice in the industry, various features are not drawn to scale. In fact, the dimensions of the various features may be arbitrarily increased or reduced for clarity of discussion.

FIG. 1A shows a schematic diagram of a quantum dot composite material, in accordance with some embodiments.

FIG. 1B is a partial enlarged schematic diagram of the quantum dot composite material shown in FIG. 1A.

FIG. 1C is a partial enlarged schematic diagram of the quantum dot composite material shown in FIG. 1A.

FIG. 2A shows a schematic diagram illustrating a carrier core of a quantum dot composite material, in accordance with some embodiments.

FIG. 2B shows a schematic diagram of a quantum dot composite material of the carrier core shown in FIG. 2A.

FIG. 3 is an FTIR graph of a quantum dot composite material, in accordance with some embodiments.

FIG. 4A is a SEM image of a quantum dot composite material after forming a cladding layer, in accordance with some embodiments.

FIG. 4B is a SEM image of the quantum dot composite material after forming the porous light-diffusion layer, in accordance with some embodiments.

FIG. 5A shows a schematic diagram illustrating a light-emitting diode chip, in accordance with some embodiments.

FIG. 5B shows a schematic diagram illustrating a light-emitting diode chip, in accordance with some embodiments.

FIG. 6A shows a schematic diagram illustrating a light-emitting diode device, in accordance with some embodiments.

FIG. 6B shows a schematic diagram illustrating a light-emitting diode device, in accordance with some embodiments.

FIG. 6C shows a schematic diagram illustrating a light-emitting diode device, in accordance with some embodiments.

FIG. 7 shows a schematic diagram illustrating a quantum dot light-emitting diode (QLED), in accordance with some embodiments.

FIGS. 8A-8C show the results of the high temperature and high humidity storage test of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. In addition, in this specification, “X to Y” which shows a range means “more than X and less than Y”.

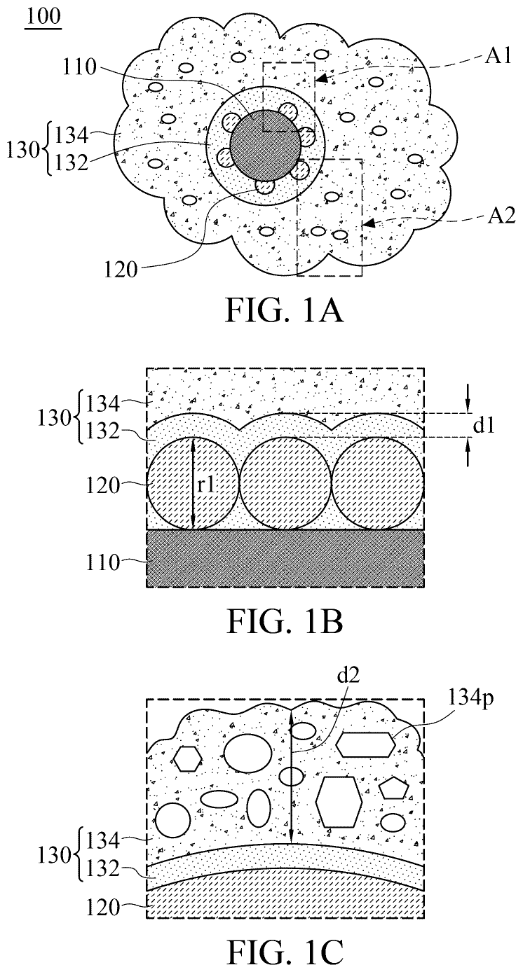

Referring to FIGS. 1A-1C, FIG. 1A shows a schematic diagram of a quantum dot composite material 100 of the present disclosure, FIG. 1B is a partial enlarged schematic diagram of region A1 in FIG. 1A, and FIG. 1C is a partial enlarged schematic diagram of region A2 in FIG. 1A. The quantum dot composite material 100 of the present disclosure includes a carrier core 110, a plurality of quantum dot particles 120, and a composite protective layer 130.

The carrier core 110 disclosed herein is used to disperse the quantum dot particles 120, enabling the quantum dot particles 120 to adhere to its surface. This reduces the self-absorption of the light emitted by the quantum dot particles 120 and reduces the amount of quantum dot particles required. In some embodiments, the carrier core 110 includes a nonactivated crystalline material, a metal oxide, or a combination thereof. The nonactivated crystalline material refers to the inorganic phosphor without activator, that is, a host lattice material without an emission center. Examples include the nonactivated crystalline nitride, oxynitride, or SiAlON; nonactivated crystalline aluminate, gallate, or aluminosilicate; or nonactivated crystalline silicate or halosilicate. The example of the metal oxide includes TiO₂, ZrO₂, Al₂O₃, MgO, CaO, SrO, or BaO. The diameter of the carrier core 110 may be, for example, 2 nm to 40 nm to evenly disperse the quantum dot particles 120 without affecting the luminous efficiency of the quantum dot particles 120.

The nonactivated crystalline material includes the nonactivated crystalline nitride, oxynitride or SiAlON, which is selected from the group consisting of: M³⁺N, M²⁺Si₂O₂N₂, M²⁺₂Si₅N₈, M³⁺₃Si₆N₁₁, M²⁺AlSiN₃, ca-silicon aluminum oxynitride (sialon) and β-silicon aluminum oxynitride; wherein M²⁺ includes Zn, Fe, Co, Ni, Cd, Cu and/or one or more alkaline earth metals; and M³⁺ includes Al, Ga, Sc, Y, La and/or one or more rare earth metals selected from the following: Sc, Y, La, Ce, Pr, Nd, Pm, Sm, Eu, Gd, Tb, Dy, Ho, Er, Tm, Yb and Lu.

The nonactivated crystalline material includes the nonactivated crystalline aluminate, gallate or aluminosilicate, which is selected from the group consisting of: M⁺AlO₂, M³⁺AlO₃, M²⁺M³⁺AlO₄, M²⁺Al₂O₄, M²⁺Al₄O₇, M⁺Al₅O₈, M³⁺4Al₂O₉, M³⁺₃Al₅O₁₂, M⁺Al₁₁O₁₇, M²⁺₂Al₁₀O₁₇, M³⁺₃Al₅O₁₂, M³⁺₃(Al,Ga)₅O₁₂, M³⁺₃Sc₂Al₃O₁₂, M²⁺₂Al₆O₁₁, M²⁺Al₈O₁₃, M²⁺M³⁺Al₁₁O₁₉, M²⁺Al₁₂O₁₉, M²⁺₄Al₁₄O₂₅, M²⁺₃Al₁₆O₂₇, M²⁺Ga₂O₄, M²⁺Ga₄O₇, M³⁺₃Ga₅O₁₂, M⁺Ga₁₁O₁₇, M²⁺Ga₁₂O₁₉, M⁺₂M²⁺₃Al₂Si₂O₁₀ and M²⁺₃Al₂Si₃O₁₂; wherein M⁺ includes one or more alkali metals; M²⁺ includes Zn, Fe, Co, Ni, Cd, Cu and/or one or more alkaline earth metals; M³⁺ includes Al, Sc, Y, La and/or one or more rare earth metals selected from the following: Sc, Y, La, Ce, Pr, Nd, Pm, Sm, Eu, Gd, Tb, Dy, Ho, Er, Tm, Yb and Lu; and X includes one or more halogens.

The nonactivated crystalline material includes an nonactivated crystalline silicate or halosilicate selected from the group consisting of: M²⁺SiO₃, M²⁺₂SiO₄, M²⁺₂(Si,Ge)O₄, M²⁺₃SiO₅, M³⁺₂SiO₅, M³⁺M⁺SiO₄, M²⁺Si₂O₅, M²⁺₂Si₂O₆, M²⁺₃Si₂O₇, M²⁺₂M⁺₂Si₂O₇, M³⁺₂Si₂O₇, M²⁺₄Si₂O₈, M²⁺₂Si₃O₈, M²⁺₃M³⁺₂Si₃O₁₂, M⁺M³⁺M²⁺₄Si₄O₁₀, M⁺M²⁺₄M³⁺Si₄O₁₄, M²⁺₃M³⁺₂Si₆O₁₈, M³⁺SiO₃X, M²⁺₃SiO₄X₂, M²⁺₅SiO₄X₆, M⁺₂M²⁺₂Si₄O₁₀X₂, M²⁺₅Si₄O₁₀X₆, M⁺₂SiX₆, M²⁺₃SiO₃X₄ and M²⁺₉(SiO₄)₄X₂; wherein M⁺ includes one or more alkali metals; M²⁺ includes Zn, Fe, Co, Ni, Cd, Cu and/or one or more alkaline earth metals; M³⁺ is Al, Sc, Y, La and/or one or more rare earth metals selected from the following: Sc, Y, La, Ce, Pr, Nd, Pm, Sm, Eu, Gd, Tb, Dy, Ho, Er, Tm, Yb and Lu; and X includes one or more halogens.

The plurality of quantum dot particles 120 disclosed herein is not particularly limited and may be appropriately selected according to the needs. For example, the quantum dot particles 120 includes II-VI semiconductors such as CdSe, CdS, etc.; III-V semiconductors such as AlP, InP, GaP, AlAs, InAs, GaAs, AlN, InN, GaNd, etc.; IV-VI semiconductors such as PbSe, PbS, etc.; or a combination thereof. The quantum dot particles 120 may include core-shell structures containing the above-mentioned compounds, such as CdSe/ZnS, InP/ZnS, etc. The plurality of quantum dot particles 120 may be evenly dispersed and adhered to the surface of the carrier core 110 by methods such as spin coating, spray coating, dip coating, physical adsorption, chemical solution growth, epitaxial growth, or electric field confinement.

In some embodiments, the quantum dot particles 120 may be excited by short-wavelength (high-energy) blue light or UV light to emit light with longer wavelength (lower energy). In some embodiments, the blue light may be provided by a blue light-emitting diode, and the UV light may be provided by a UV light-emitting diode. In some embodiments, under the excitation by blue light or UV light, the emission wavelength of the quantum dots 120 is greater than that of the blue light or UV light. For example, the quantum dot particles 120 may be yellow, red, or green quantum dot particles, which may emit yellow light, red light or green light when excited by blue light or UV light. In some embodiments, the diameter r1 of the plurality of quantum dot particles 120 may be appropriately selected according to the wavelength to be emitted. The larger the quantum dot particles are, the longer the emission wavelength (red shift) is, for example approaching the red region of the spectrum, while the smaller the quantum dot particles are, the shorter the emission wavelength (blue shift) is, for example closer to the blue end of the spectrum. For example, the larger quantum dots with a diameter of 5-6 nm or more emit longer wavelength, such as emitting orange or red light, while the smaller quantum dots with a diameter of 2-3 nm or less emit shorter wavelength, such as emitting blue or green light. In some embodiments, the quantum dot particles 120 may be core-shell quantum dot particles. The shell layer may improve quantum yield and make the quantum dots more durable. Therefore, the thickness of the shell layer may be selected according to the demanded physical properties (e.g., light conversion efficiency, heat resistance, etc.).

Next, a composite protective layer 130 is formed to cover the carrier core 110 and the quantum dot particles 120. The composite protective layer 130 includes a cladding layer 132 and a porous light-diffusion layer 134. By the cladding layer 132, the present disclosure may reduce the effects of moisture and/or oxygen in the environment on the quantum dot composite material 100. Furthermore, the pores of the porous light-diffusion layer 134 may evenly diffuse the excitation light (e.g., blue light or UV light) incident on the quantum dot composite material 100, thereby improving the light resistance of the quantum dot composite material 100.

BET specific surface area is short for the BET specific surface area test method. BET is the acronym for three scientists (Brunauer, Emmett, and Teller). The total surface area occupied by 1 g of a solid is the specific surface area S (m²/g) of the substance. In some embodiments, the BET specific surface area of the composite protective layer 130 is 0.5 to 50 m²/g, for example, about 1 to 45 m²/g, about 3 to 40 m²/g, about 5 to 35 m²/g, about 8 to 30 m²/g, about 10 to 25 m²/g, about 15 to 20 m²/g, etc. By setting the BET specific surface area of the composite protective layer 130 within the above range, the light incident on the quantum dot composite material 100 may be evenly diffused, and the luminous efficiency of the quantum dot particles 120 may be maintained.

The cladding layer 132 includes a light-transmitting material, which reduces the impact of the environment on the quantum dot particles 120 while not affecting the luminescence of the quantum dot particles 120. In some embodiments, the cladding layer 132 may comprise a metal oxide, such as TiO₂, ZrO₂, Al₂O₃, MgO, CaO, SrO, BaO, or a combination thereof. The cladding layer 132 may be single layer or multiple layers, each layer may comprise the same or different materials, and each layer may have the same or different thicknesses.

In some embodiments, the cladding layer 132 may be formed conformably on the carrier core 110 and the quantum dot particles 120 by atomic layer deposition (ALD), so that the surface shape of the cladding layer 132 corresponds to the surface shape of the quantum dot particles 120 and the carrier core 110 thereunder. In some embodiments, the reaction temperature of the ALD process may be greater than or equal to 60° C. and less than or equal to 180° C. For example, the reaction temperature of the ALD process may be 60° C., 70° C., 80° C., 90° C., 100° C., 110° C., 120° C., 130° C., 140° C., 150° C., 160° C., 170° C., 180° C., or a value or range of values therebetween, but the present disclosure is not limited thereto.

In some embodiments, as shown in FIG. 1B, the thickness d1 of the cladding layer 132 is defined as the distance between the quantum dot particle 120 and the adjacent surface of the cladding layer 132. The thickness d1 is about 1 nm to 10 nm, for example, about 2 nm to 9 nm, about 3 nm to 8 nm, about 4 nm to 7 nm, about 5 nm to 6 nm, etc. In some embodiments, the ratio (r1:d1) of the diameter r1 of the quantum dot particle 120 to the thickness d1 of the cladding layer 132 is about 1:0.2 to 1:0.5, for example, about 1:0.25 to 1:0.48, about 1:0.28 to 1:0.45, about 1:0.3 to 1:0.43, about 1:0.33 to 1:0.4, about 1:0.35 to 1:0.38, etc. By controlling the thickness d1 of the cladding layer 132 and the ratio (r1:d1) of the diameter r1 of the quantum dot particle 120 to the thickness d1 of the cladding layer 132 within the above ranges, the luminous efficiency of the quantum dot particles 120 may be maintained while protecting the quantum dot particles 120 from degradation due to environmental factors.

The porous light-diffusion layer 134 includes a light-transmissive material and an irregular surface for diffusing the light incident on the quantum dot particles 120. In some embodiments, as shown in FIG. 1C, the thickness d2 of the porous light-diffusion layer 134 is defined as the distance between the surface of the cladding layer 132 and the surface of the porous light-diffusion layer 134. The thickness d2 is 100 nm to 1 m, for example, about 150 nm to 950 nm, about 200 nm to 900 nm, about 250 nm to 850 nm, about 300 nm to 800 nm, about 350 nm to 750 nm, about 400 nm to 700 nm, about 450 nm to 650 nm, about 500 nm to 600 nm, about 550 nm to 580 nm, etc. In some embodiments, the ratio (r1:d2) of the diameter r1 of the quantum dot particle 120 to the thickness d2 of the porous light-diffusion layer is from 1:5 to 1:50, for example, from 1:10 to 1:45, from 1:15 to 1:40, from 1:20 to 1:35, from 1:25 to 1:30, etc. By controlling the thickness of the porous light-diffusion layer 134 and the ratio (r1:d2) of the diameter r1 of the quantum dot particle 120 to the thickness d2 of the porous light-diffusion layer 134 within the above range, the light resistance of the quantum dot particle 120 may be improved while maintaining the luminous efficiency of the quantum dot particle 120.

In some embodiments, the ratio (d1:d2) of the thickness d1 of the cladding layer 132 to the thickness d2 of the porous light-diffusion layer 134 is from 1:10 to 1:250, for example, from 1:30 to 1:230, from 1:50 to 1:210, from 1:70 to 1:200, from 1:90 to 1:180, from 1:100 to 1:160, from 1:120 to 1:150, from 1:130 to 1:140, etc. By controlling the ratio (d1:d2) of the thickness d1 of the cladding layer 132 to the thickness d2 of the porous light-diffusion layer 134 within the above range, the light resistance of the quantum dot particles 120 may be improved while maintaining the luminous efficiency of the quantum dot particles 120.

The porous light-diffusion layer 134 includes a plurality of pores 134p for diffusing the light paths. In some embodiments, the volume of the pores 134p is 0.01 to 0.5 cm³/g, such as about 0.03 to 0.45 cm³/g, about 0.05 to 0.4 cm³/g, about 0.1 to 0.35 cm³/g, about 0.15 to 0.3 cm³/g, or about 0.2 to 0.3 cm³/g. By controlling the volume of the pores 134p in the porous light-diffusion layer 134 within the above range, the light may be effectively diffused without affecting the luminous efficiency of the quantum dots.

In some embodiments, the porous light-diffusion layer 134 includes an inorganic compound, an organic compound, or a combination thereof. Examples of the inorganic compound include SiOR, SiO₂, Si(OR)₄, or Si(OMe)₃C₃H₆S, other silica materials; metal oxides such as Al₂O₃; metal nitrides; nitrides such as Si₃N₃; or a combination thereof, wherein each of the R groups independently represents a C1-C20 alkyl group. Examples of the organic compound include polymethyl methacrylate (PMMA), polyethylene terephthalate (PET), polystyrene (PS), polypropylene (PP), polyamide (PA), polycarbonate (PC), polyimide (PI), epoxy, polydimethylsiloxane (PDMS), silicone, and a combination thereof.

In some embodiments, the porous light-diffusion layer 134 may be formed by a sol-gel method. For example, a powder of quantum dot particles 120 dispersed on the carrier core 110 and covered by the cladding layer 132 is placed in 400 ml to 600 ml of solvent such as methanol or ethanol, and then about 10 ml to 30 ml of a precursor and optionally the above-mentioned organic compound are added, and stirred at about 15° C. to 80° C. for about 45 to 80 minutes. Next, 3 to 10 ml of a catalyst (for example, acid such as HCl, H₂SO₄ and HNO₃, and alkaline such as NaOH and NH₄OH) is then added to the reaction flask, and stirred at about 15° C. to 80° C. for 1 to 6 hours. This material is washed several times with n-hexane and dried at about 50° C. to 80° C. for 3 to 5 hours to obtain the quantum dot composite material disclosed herein.

Examples of the metal alkoxide as the precursor includes monometallic alkoxide such as Si(OCH₃)₄, Si(OC₂H₅)₄, Ti(OCH₃)₄, Ti(OC₂H₅)₄, Zr(OCH₃)₄, Zr(OC₂H₅)₄, Al(OCH₃)₃, Al(OC₂H₅)₃, etc.; or bimetallic alkoxide such as La[Al(iso-OC₃H₇)₄]₃, Mg[Al(iso-OC₃H₇)₄]₂, Ni[Al(iso-OC₃H₇)₄]₂, (C₃H₇O)₂Zr[Al(OC₃H₇)₄]₂, Ba[Zr(OC₂H₅)₉]₂, etc. Examples of the metal salt as the precursor include nitrate, sulfate, acetate, sulfide, chloride, etc. of metal such as aluminum, hafnium, silicon, zirconium, titanium, lanthanum, germanium, tantalum, etc.

When the porous light-diffusion layer 134 only includes organic compounds, the porous light-diffusion layer 134 may be formed by, but not limited to, chemical solution growth method and/or sol-gel method.

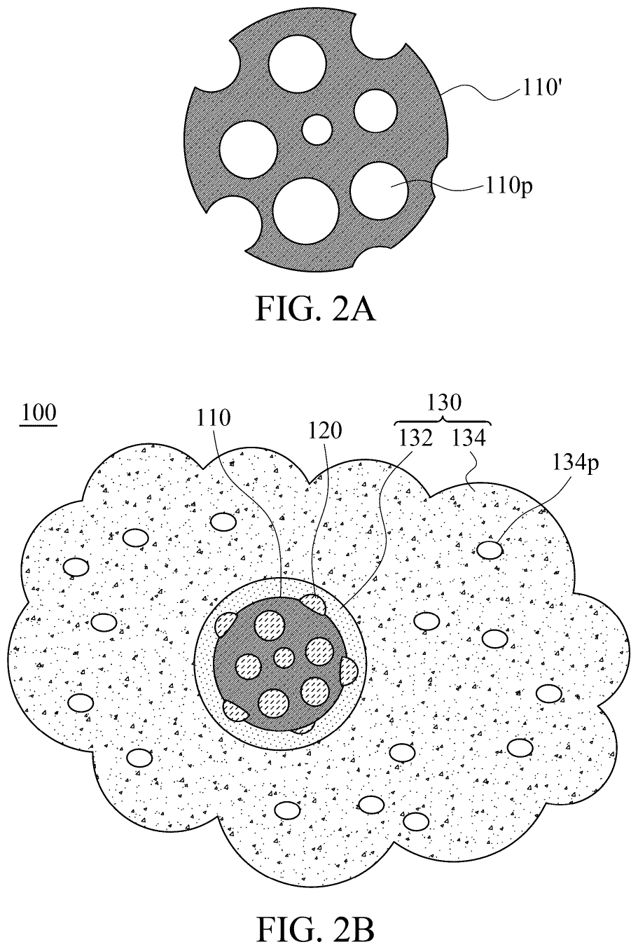

Referring now to FIG. 2A and FIG. 2B. FIG. 2A is a schematic diagram illustrating a carrier core of a quantum dot composite material according to other embodiments. FIG. 2B is a schematic diagram illustrating a quantum dot composite material having the carrier core shown in FIG. 2A. In some embodiments, a porous substrate may be utilized as the carrier core 110′ of the quantum dot composite material 100. The carrier core 110′ includes an outer surface with a plurality of recessed holes 110p for accommodating the quantum dot particles 120. The size of the recessed hole 110p may be appropriately designed based on the particle size of the quantum dot particle 120. For example, the size of the recessed hole 110p may be greater than or substantially equal to the particle size of the quantum dot particle 120 to accommodate the quantum dot particle 120 therein. In some embodiments, the size of the recessed hole 110p is about 1 nm to 100 nm, such as about 5 nm to 95 nm, about 10 nm to 90 nm, about 15 nm to 85 nm, about 20 nm to 80 nm, about 30 nm to 75 nm, about 35 nm to 70 nm, about 40 nm to 65 nm, about 45 nm to 60 nm, or about 50 nm to 55 nm. In some embodiments, the material of the carrier core 110′ may include a highly transparent material such as silica, glass, etc., so as not to reduce the light extraction efficiency of the quantum dot particles 120.

Since the carrier core 110′ includes a high specific surface area, it can strongly adsorb the quantum dot particle 120, allowing the quantum dot particle 120 to enter the pore through physical adsorption. For example, in some embodiments, the quantum dot particles 120 may be dissolved in the solvent such as hexane, and then the carrier core 110′ is added to the solution of the quantum dot particles 120. The mixture is mixed at a ratio of about 1:8 to 1:15 of total quantum dot particles 120 to the carrier core 110′, and is stirred for about one hour. The mixture is then centrifuged at 2000-5000 rpm for 5-15 minutes to obtain a powder of the quantum dot particles 120 accommodated in the carrier core 110′. Next, the cladding layer 132 and the porous light-diffusion layer 134 are formed. The materials, thickness, and formation methods of the cladding layer 132 and the porous light-diffusion layer 134 may be referred to the embodiments described above with reference to FIG. 1A to FIG. 1C, and are not further described here.

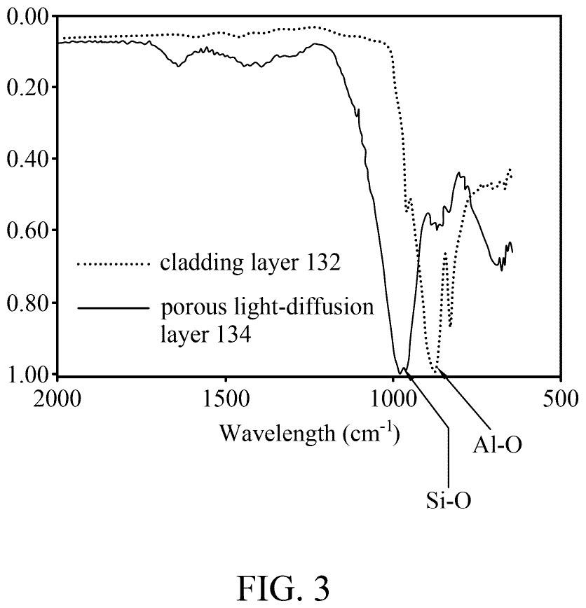

Referring next to FIG. 3, which is an FTIR graph of a quantum dot composite material in some embodiments, the quantum dot composite material 100 disclosed herein clearly shows an Al—O peak of the cladding layer 132 and a Si—O peak of the porous light-diffusion layer 134, indicating that the quantum dot composite material 100 comprises the cladding layer 132 and the porous light-diffusion layer 134 formed thereon.

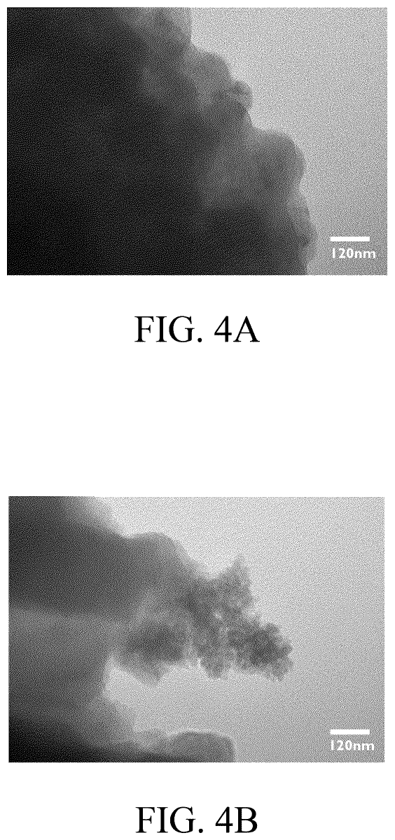

Referring to FIG. 4A and FIG. 4B, FIG. 4A is a SEM image of the quantum dot composite material 100 after forming a cladding layer 132 in some embodiment, and FIG. 4B is a SEM image after forming a porous light-diffusion layer 134 on the cladding layer 132. It can be clearly seen that the cladding layer 132 has a relatively dense structure, while the porous light-diffusion layer 134 has a relatively loose structure and an irregular surface. In this embodiment, the BET specific surface area of the cladding layer 132 is 0.4 m²/g, and the BET specific surface area of after formation of the porous light-diffusion layer 134 is 7.9 m²/g.

The quantum dot composite material 100 disclosed herein may be used in various light-emitting devices, such as lighting-related applications, automotive lighting, or display applications, the light-emitting modules (frontlight modules or backlight modules) of displays such as mobile phone screen, television screen, and car dashboard, and panel pixels or sub-pixels of displays.

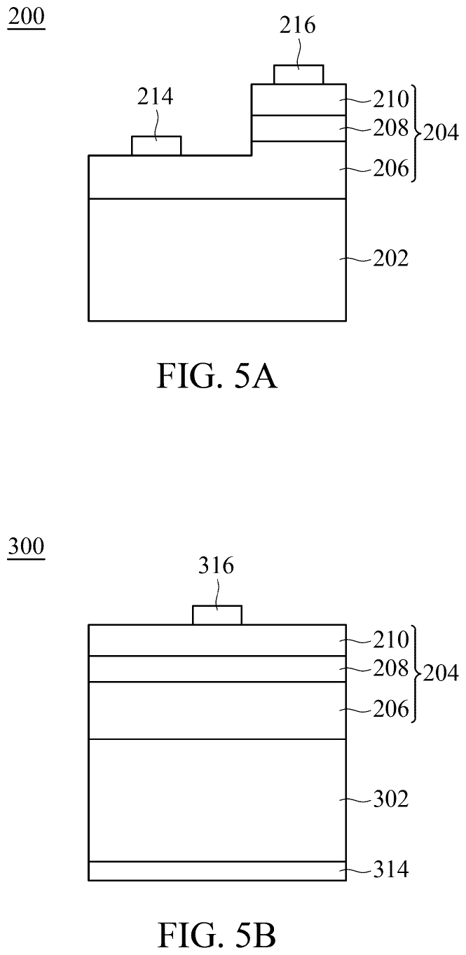

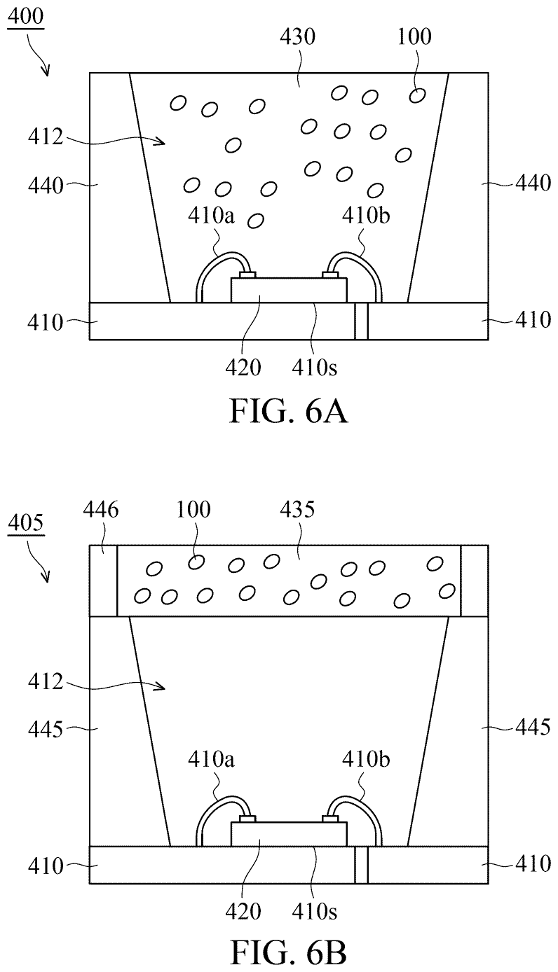

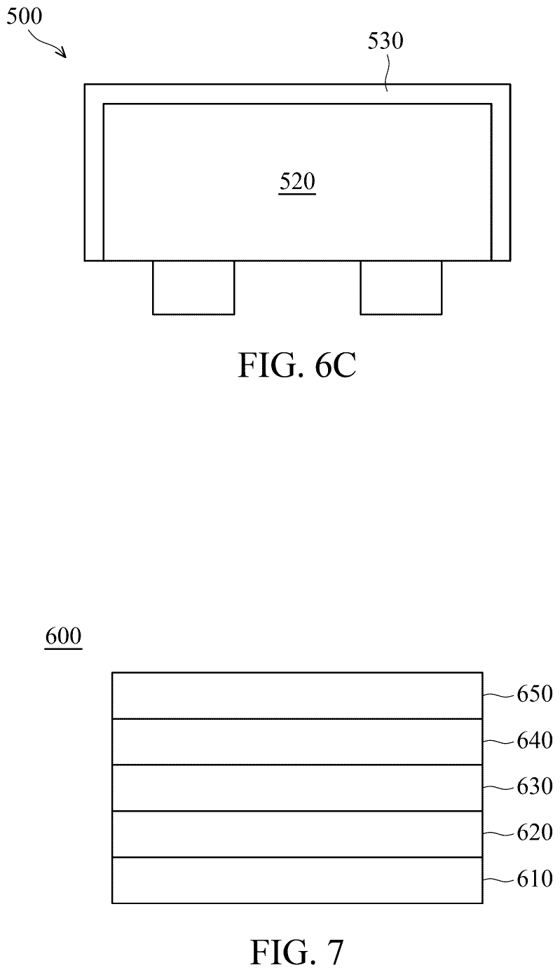

For example, the quantum dot composite material 100 disclosed herein may be used as a wavelength-converting material in a light-emitting device, for example, incorporated into a wavelength-converting layer and/or doped into a light-transmitting substrate. In some embodiments, the wavelength-converting material may be coated on the light-emitting surface of a light-emitting diode chip. The LED light-emitting devices in some embodiments of the present disclosure are described below with reference to FIGS. 5A-5B and FIGS. 6A-6C.

FIG. 5A illustrates a diode chip 200 in a light-emitting device according to some embodiments. The light-emitting diode chip 200 includes a substrate 202, an epitaxial structure 204, a first electrode 214, and a second electrode 216. The epitaxial structure 204 includes a first-type semiconductor layer 206, an active layer 208, and a second-type semiconductor layer 210 stacked sequentially from the substrate 202. The first electrode 214 and the second electrode 216 are connected to the first-type semiconductor layer 206 and the second-type semiconductor layer 210, respectively. The substrate 202 may include an insulating material (e.g., sapphire) or a semiconductor material. The first-type semiconductor layer 206 and the second-type semiconductor layer 210 have opposite conductivity types. For example, the first-type semiconductor layer 206 may include an N-type semiconductor layer, while the second-type semiconductor layer 210 may include a P-type semiconductor layer. The first electrode 214 may be an N-electrode, while the second electrode 216 may be a P-electrode. For example, the first-type semiconductor layer 206 includes a P-type semiconductor layer, and the second-type semiconductor layer 210 includes an N-type semiconductor layer, wherein the first electrode 214 is a P-electrode and the second electrode 216 is an N-electrode. The LED chip 200 may be mounted by either a face-up or a flip-chip mounting method. In the embodiments using flip chip mounting method, the LED chip 200 is turned upside down so that the first electrode 214 and the second electrode 216 face towards the substrate such as a circuit board and are electrically connected to the contact pads through solder.

FIG. 5B illustrates a vertical LED chip 300 in a light-emitting device according to another embodiment. The LED chip 300 includes a substrate 302 and an epitaxial structure 204. The epitaxial structure 204 includes a first-type semiconductor layer 206, an active layer 208, and a second-type semiconductor layer 210 stacked sequentially from the substrate 302. A first electrode 314 and a second electrode 316 are connected to the substrate 302 and the second-type semiconductor layer 210, respectively. The material of the substrate 302 may be a metal, an alloy, a conductor, a semiconductor, or a combination thereof. The substrate 302 may include a semiconductor material having the same conductivity type as the first-type semiconductor layer 206, or a conductive material such as a metal that can form an ohmic contact with the first-type semiconductor layer 206. For example, the first-type semiconductor layer 206 comprises an N-type semiconductor layer, and the second-type semiconductor layer 210 comprises a P-type semiconductor layer, wherein the first electrode 314 is an N-electrode and the second electrode 316 is a P-electrode. For example, the first-type semiconductor layer 206 comprises a P-type semiconductor layer, and the second-type semiconductor layer 210 comprises an N-type semiconductor layer, wherein the first electrode 314 is a P-electrode and the second electrode 316 is an N-electrode.

In some embodiments, the P-type semiconductor layer may be a P-type GaN material, and the N-type semiconductor layer may be an N-type GaN material. In some embodiment, the P-type semiconductor layer may be a P-type AlGaN material, and the N-type semiconductor layer may be an N-type AlGaN material. The active layer 208 includes a multiple quantum well structure.

In some embodiments, the wavelength of the first light emitted by the LED chips 200 and 300 is 220 nm to 480 nm. In some embodiments, the LED chips 200 and 300 may be ultraviolet LED chips, and the wavelength of the first light emitted is 200 nm to 400 nm. In some embodiments, the LED chips 200 and 300 may be blue LED chips, and the wavelength of the first light emitted is 430 nm to 480 nm.

FIG. 6A illustrates a schematic diagram of a light-emitting diode device according to some embodiments. In some embodiments, the light-emitting diode device 400 includes a base 410, a light-emitting diode (LED) chip 420, a wavelength-converting layer 430, and a reflective wall 440. The base 410 has a positive electrode 410a and a negative electrode 410b. The base 410 has a die-bonding region 410s on its upper surface. The reflective wall 440 is located on the base 410, surrounds the die-bonding region 410s and defines an accommodation space 412. The LED chip 420 may be the LED chips 200 and 300 described above, and is disposed in the accommodation space 412 and fixed to the die-bonding region 410s of the base 410. The LED chip 420 may emit blue light or UV light. Furthermore, the LED chip 420 may be a small-sized LED chip, such as a mini LED chip or a micro LED chip. The LED chip 420 may be mounted face-up as shown in FIG. 6A, or alternatively, in a flip-chip configuration as needed. A wavelength-converting layer 430 is disposed on the light-emitting surface of the LED chip 420. The wavelength-converting layer 430 comprises a transparent gel and the quantum dot composite material 100 of the present disclosure as shown in FIGS. 1A-1C or FIGS. 2A-2B. Examples of the material of the transparent gel include polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), epoxy, and silicone, or a combination of two or more of the materials.

According to some embodiments of the present disclosure, in addition to the quantum dot composite material 100 of the present disclosure, the wavelength-converting layer 430 may also be mixed with other phosphors or quantum dot composite materials 100 that emit different colors, depending on color requirements. Taking the LED device 400 emitting white light and LED chip 420 emitting blue light as an example, the wavelength-converting layer 430 includes the green quantum dot composite material 100 and the red quantum dot composite material 100. Taking the LED device 400 emitting white light and the LED chip 420 emits UV light as an example, the wavelength-converting layer 430 includes a blue quantum dot composite material 100, a green quantum dot composite material 100, and a red quantum dot composite material 100. The amount of powder used in the wavelength-converting layer 430 is not particularly limited. For example, in some embodiments, the amount of powder used in the wavelength-converting layer 430 may be 50 wt % to 80 wt %, meaning that the transparent gel 432 contains a total of 50 wt % to 80 wt % of the quantum dot composite material 100 and other phosphors.

FIG. 6B shows another schematic diagram of a light-emitting diode (LED) device 405 according to other embodiments. The light-emitting diode device (LED) 405 includes a LED chip 420, a base 410, a cup wall 445, a wavelength-converting layer 435, and a reflective wall 446. The base 410 includes a positive electrode 410a and a negative electrode 410b. The base 410 includes a die-bonding region 410s on its upper surface. The cup wall 445 is located on the base 410, surrounds the die-bonding region 410s and defines an accommodation space 412. The LED chip 420 is disposed in the accommodation space 412 and fixed to the die-bonding region 410s of the base 410. The wavelength-converting layer 435 is disposed on the light-emitting side of the LED chip 420 and on the top surface of the cup wall 445. The reflective wall 446 may be disposed to surround the outer sidewalls of the wavelength-converting layer 435 and on the top surface of the cup wall 445. The reflective wall 446 includes a light-reflecting and low-light-leakage material, such as reflective glass, quartz, a light-reflection attaching sheet, a polymer plastic, or other suitable material. The polymer plastic material may comprise polymethyl methacrylate (PMMA), polyethylene terephthalate (PET), polystyrene (PS), polypropylene (PP), polyamide (PA), polycarbonate (PC), epoxy, silicone, etc., or a combination thereof. The light reflectivity of the reflective wall 446 may be modified by adding additional filler particles. The filler particles may be a composite material with different particle sizes or different materials. For example, the material for the filler particle may comprise titanium dioxide (TiO₂), silicon dioxide (SiO₂), aluminum oxide (Al₂O₃), boron nitride (BN), zinc oxide (ZnO), etc. In this embodiment, the LED chip 420 and the wavelength-converting layer 435 are separated by air gap in the accommodation space 412 defined by the cup wall 445. In other words, the accommodation space 412 may be unfilled with any other material in contact with the LED chip 420, that is, the accommodation space 412 is air.

The wavelength-converting layer 435 includes a transparent gel and the quantum dot composite material 100 shown in FIG. 1A-1C or 2A-2B. The material of the transparent gel of the wavelength-converting layer 435 may refer to the material of the transparent gel of the wavelength-converting layer 430 and is not further described here. In some embodiments, the wavelength-converting layer 435 is separated from the LED chip 420 (in this example, is separated by the accommodation space 412). This prevents the wavelength-converting layer 435 from being too close to the LED chip 420, which could affect its thermal and chemical stability. This improves the lifespan of the wavelength-converting layer 435 and enhances the reliability of the LED package structure product. In another embodiment, the air gap within the accommodation space 412 defined by the cup wall 445 may be filled with a transparent encapsulant (not shown). The transparent encapsulant includes polymethyl methacrylate, polyethylene terephthalate, polystyrene, polypropylene, nylon, polycarbonate, polyimide, polydimethylsiloxane, epoxy resin, silicone, etc., or a combination thereof. In some embodiments, the transparent encapsulant may be doped with one or more wavelength-converting materials. In other transformable embodiments, one or more wavelength-converting materials may be coated on the light-emitting surface of the LED chip 420. Therefore, in addition to the wavelength-converting layer 435, the light-emitting properties of the LED device 405 may be further adjusted by the (transparent) encapsulant with the wavelength-converting material and/or the coating layer with the wavelength-converting material on the surface of the LED chip 420. The type of wavelength-converting material in the wavelength-converting layer 435, the encapsulant, and/or the coating layer may be adjusted appropriately based on the actual product requirements.

FIG. 6C illustrates another schematic diagram of a light-emitting diode device according to other embodiments. The light-emitting diode device 500 includes a light-emitting diode chip 520 and a wavelength-converting layer 530. The light-emitting diode chip 520 is of flip-chip type, and the wavelength-converting layer 530 includes the quantum dot composite material 100 and a transparent gel. The wavelength-converting layer 530 conformally covers the top surface and sidewalls of the light-emitting diode chip 520. The material of the transparent gel of the wavelength-converting layer 530 may refer to the material of the transparent gel of the wavelength-converting layer 430 and is not further described here.

Light-emitting diode devices may be of various types and are not limited to the light-emitting diode devices shown in FIGS. 6A to 6C. Furthermore, the quantum dot composite material 100 disclosed herein may also be applied to quantum dot light-emitting diodes (QLEDs). The quantum dot LED (QLED) is explained below with reference to the figures.

FIG. 7 illustrates a schematic diagram of a quantum dot light-emitting diode (QLED) according to some embodiments. The quantum dot light-emitting diode 600 includes an anode 610, a hole injection layer 620, a light-emitting layer 630, an electron injection layer 640, and a cathode 650 stacked in sequence. The light-emitting layer 630 includes the quantum dot composite material 100, such as a red quantum dot composite material 100, a green quantum dot composite material 100, a blue quantum dot composite material 100, or a combination thereof. The anode 610 and the cathode 650 may include transparent conductors such as indium tin oxide (ITO), indium zinc oxide (IZO), zinc oxide, titanium nitride, or polyaniline, etc.; or opaque conductors such as aluminum, lithium-aluminum alloy, silver, magnesium-silver alloy, or lithium fluoride-aluminum (LiF:Al), etc. The hole injection layer 620 may include, for example, PEDOT:PSS, HATNA-F6, MeO- or Spiro-TPD, etc., while the electron injection layer 640 may include, for example, NTCDA, BCP, or 3TPYMB, etc.

In order to make the above contents and other purposes, features, and advantages of the present disclosure more clearly understood, the following provides specific embodiments, along with the accompanying drawings, for detailed explanation.

### Experimental Example 1

CdSe quantum dot particles were dissolved in hexane solvent. Then silicate serving as a carrier core was added to the quantum dot solution. The mixture was mixed at a ratio of about 1:0.03 of total quantum dot particles to the carrier cores and stirred for about one hour. The mixture was then centrifuged at 9000 rpm for one minute to obtain a powder of the quantum dot particles accommodated on the carrier cores. Aluminum oxide was then deposited on the carrier cores and the quantum dot particles by atomic layer deposition to form a cladding layer.

Next, the powder obtained above was placed in 500 ml of ethanol, and 20 ml of tetraethoxysilane was added as a Si precursor. The mixture was stirred at 60° C. for about 60 minutes. Then 5 ml of aqueous ammonia as a catalyst was then added to the reaction flask, and the temperature was maintained at 60° C. for 6 hours. The composite material was washed several times with n-hexane and dried at 60° C. for 4 hours to form a porous light-diffusion layer, thereby producing the composite material structure of the present disclosure.

The quantum dot composite material described above is mixed with an organic siloxane resin and then coated on a blue light-emitting diode chip capable of emitting a wavelength of about 450-460 nm, having an optical power of about 34.6 mW, and with a chip size of about 0.35 mm*0.70 mm to obtain the light-emitting device as shown in FIG. 6A, wherein the powder loading of the light-emitting device is 75 wt %, i.e., the wavelength-converting layer of the light-emitting device comprises 75 wt % of the quantum dot composite material and 25 wt % of the organosiloxane resin.

### Comparative Example 1

A light-emitting device was manufactured in the same manner as in Experimental Example 1, except that only the cladding layer described in Experimental Example 1 was formed as the protective layer for the quantum dot composite material.

### Comparative Example 2

A light-emitting device was manufactured in the same manner as in Experimental Example 1, except that only the porous light-diffusion layer described in Experimental Example 1 was formed as the protective layer for the quantum dot composite material.

### <High Temperature and High Humidity Storage Test>

The manufactured light-emitting devices were subjected to a high-temperature and high-humidity storage test. The purpose of the test is to verify the heat aging resistance of the packaging material. Different currents were applied to the manufactured light-emitting devices to induce emission. The chromaticity (Cy) and luminous intensity (IV) of each light-emitting device were measured using a brightness measurement instrument (Weiming Enterprise/6122) according to the HHO6090 standard. Afterwards, the light-emitting devices under the illuminated state were placed in a test oven at a temperature of 60° C. and a humidity of 90%. The chromaticity (Cy) and luminous intensity of the light-emitting devices were measured at 1, 24, and 96 hours after exposure to high temperature and high humidity. Then, starting from the 168th hour, the manufactured light-emitting devices were removed from the test oven every 168 hours for measurement, up to the 840th hour. Measurements were thus conducted at 168, 336, 504, 672, and 840 hours. The luminous intensity and chromaticity measured before placing in the test oven were used as a reference to calculate the degree of luminous intensity decay over time and the chromaticity deviation of the light-emitting devices.

The degree of luminous intensity decay over time and the chromaticity deviation are calculated as follows:

The degree of luminous intensity decay after exposure to high temperature and high humidity for n hours is:

(Luminous intensity after n hours under high temperature and high humidity)/(Luminous intensity before high temperature and high humidity)×100%

The chromaticity deviation after n hours of high temperature and high humidity is:

(Chromaticity after n hours of high temperature and high humidity)−(Chromaticity before high temperature and high humidity)

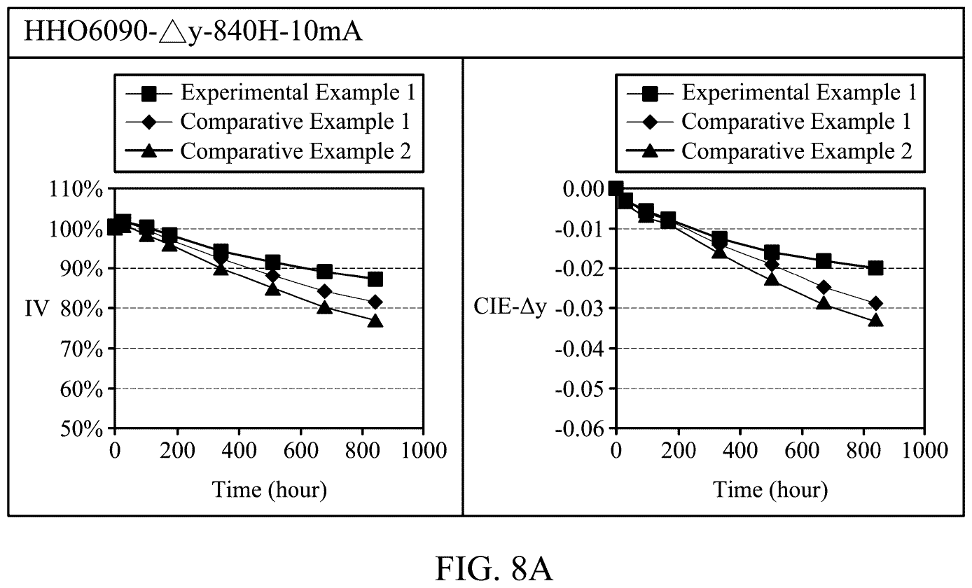

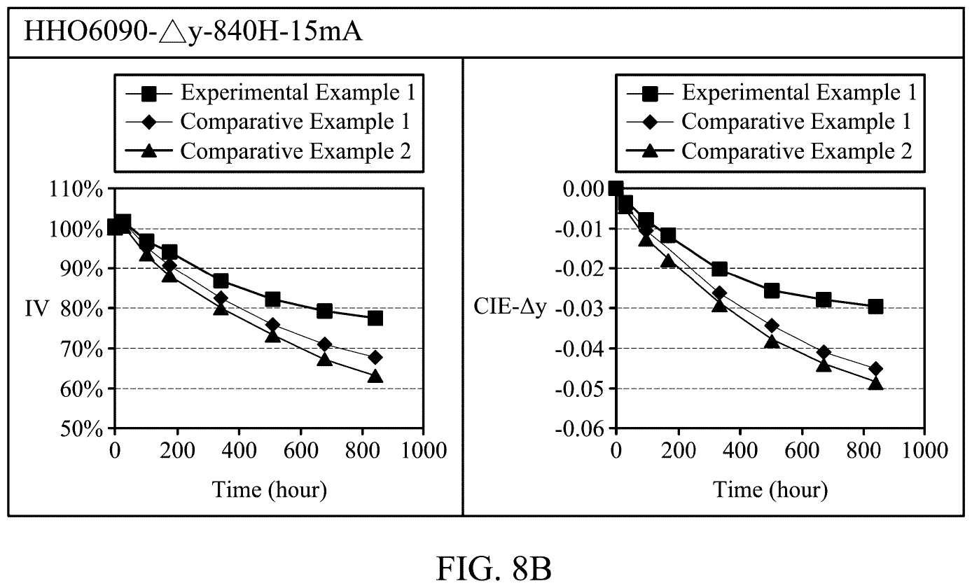

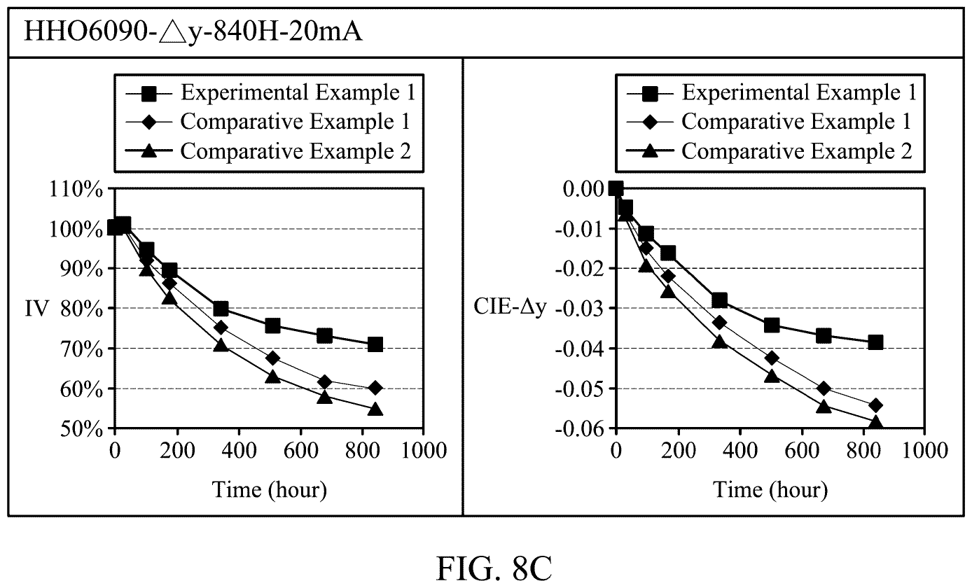

Experimental Example 1 and Comparative Examples 1-2 were subjected to high-temperature, high-humidity storage tests at currents of 10 mA, 15 mA, and 20 mA, respectively. The results are shown in FIGS. 8A-8C. The experimental results show that, regardless of the current of 10 mA, 15 mA, or 20 mA, the degree of luminous intensity decay and chromaticity deviation of Comparative Example 1, which includes only the cladding layer as the protective layer, and Comparative Example 2, which includes only the porous light-diffusion layer as the protective layer, are significantly greater than those of Experimental Example 1, which includes both the cladding layer and the porous light-diffusion layer as the protective layer.

### <BET Specific Surface Area Measurement>

The BET specific surface area of the composite materials prepared in Experimental Example 1 and Comparative Examples 1-2 was measured using ASAP 2020 instrument made by Micromeritics.

### <Luminous Flux Measurement>

Luminous flux measurements were performed on the light-emitting devices produced in Experimental Example 1 and Comparative Example 1-2 using an integrating sphere (IS) instrument. Specifically, the electrical current was applied to the light-emitting devices to induce emission, and the luminous flux (lm) was measured. The results are shown in Table 1.

Next, using the above-mentioned high-temperature and high-humidity storage test method, the degree of luminous intensity decay of the device at 10 mA current after 840 hours of high-temperature and high-humidity storage, denoted as HHO6090 IV %-840H-10 mA, was obtained, along with the chromaticity deviation, denoted as HHO6090Δy-840H-10 mA and RTOΔy-840H-10 mA. The results are shown in Table 1.

TABLE 1

| | Comparative | Experimental | Comparative |
|---|---|---|---|
| # | Example 1 | Example 1 | Example 2 |
| Protective layer | cladding layer | composite | porous light- |
| | | protective layer | diffusion layer |
| Powder loading (wt %) | 75 | 75 | 75 |
| BET specific surface | 0.004 | 25 | 150 |
| area (m²/g) | | | |
| Luminous flux (lm) | 8.93 | 7.73 | 5.97 |
| HHO6090 | 81% | 87% | 77% |
| IV %-840H-10mA | | | |
| HHO6090 | −0.029 | −0.02 | −0.033 |
| Δy-840H-10mA | | | |
| RTOΔy-840H-10mA | −0.023 | −0.01 | −0.018 |

As shown in Table 1, the comparative Example 1, which uses only the cladding layer as the protective layer, exhibits higher luminous flux, but it shows larger chromaticity deviation and inferior thermal aging resistance compared to the experimental Example 1, which uses the composite protective layer. Furthermore, the comparative Example 2, which uses only a porous light-diffusing layer as the protective layer, not only exhibits lower luminous flux but also shows larger chromaticity deviation and lower thermal aging resistance relative to the Experimental Example 1.

In summary, the quantum dot composite material disclosed herein may be used in various light-emitting devices and has heat aging resistance, thereby enhancing performance stability and extending the lifespan of a wide range of device applications.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A quantum dot composite material, including:
a carrier core;
a plurality of quantum dot particles attached to the carrier core; and
a composite protective layer covering the carrier core and the plurality of quantum dot particles, and including a cladding layer and a porous light-diffusion layer which include light-transmissive materials,
wherein the cladding layer is conformably formed on the carrier core and the plurality of quantum dot particles, and the porous light-diffusion layer is formed on the cladding layer and includes an irregular surface.

2. The quantum dot composite material as claimed in claim 1, wherein the porous light-diffusion layer includes a thickness of 100 nm to 1 μm, and the cladding layer includes a thickness of 1 nm to 10 nm.

3. The quantum dot composite material as claimed in claim 1, wherein the composite protective layer includes a BET specific surface area of 0.5 to 50 m²/g.

4. The quantum dot composite material as claimed in claim 1, wherein the porous light-diffusion layer includes multiple pores, and the pores include a volume of 0.01~0.5 cm³/g.

5. The quantum dot composite material as claimed in claim 1, wherein the porous light-diffusion layer includes inorganic compound, organic compound or a combination thereof.

6. The quantum dot composite material as claimed in claim 1, wherein the cladding layer includes metal oxide.

7. The quantum dot composite material as claimed in claim 1, wherein a ratio of a diameter of the plurality of quantum dot particles to a thickness of the cladding layer is 1:0.2 to 1:0.5.

8. The quantum dot composite material as claimed in claim 1, wherein a ratio of a diameter of the plurality of quantum dot particles to a thickness of the porous light-diffusion layer is 1:5 to 1:50.

9. The quantum dot composite material as claimed in claim 1, wherein a ratio of a thickness of the cladding layer to a thickness of the porous light-diffusion layer is 1:10 to 1:250.

10. The quantum dot composite material as claimed in claim 1, wherein the carrier core includes a nonactivated crystalline material, a metal oxide, or a combination thereof.

11. The quantum dot composite material as claimed in claim 1, wherein the carrier core includes an outer surface with a plurality of recessed holes for accommodating the plurality of quantum dot particles.

12. The quantum dot composite material as claimed in claim 1, wherein the plurality of quantum dot particles includes core-shell quantum dot particles.

13. A light-emitting device, comprising the quantum dot composite material claimed in claim 1.
